(19) United States
(12) Patent Application Publication
(10) Pub. No.: US 2026/0059713 A1
(43) Pub. Date: Feb. 26, 2026

(54) HIGH THERMAL CAPACITY HEAT SINK

(71) Applicant: ICEOTOPE GROUP LIMITED, Rotherham (GB)

(72) Inventors: Neil EDMUNDS, Sheffield (GB); Alexander CUSHEN, South Yorkshire (GB); Oliver HEYES, Sheffield (GB); David AMOS, Sheffield (GB)

(21) Appl. No.: 18/851,986

(22) PCT Filed: Mar. 28, 2023
(86) PCT No.: PCT/GB2023/050794

§ 371 Date: Sep. 27, 2024

(30) Foreign Application Priority Data
Apr. 1, 2022 (GB) 2204760.9

(51) Int. Cl. H05K 7/20

(52) U.S. Cl. CPC H05K 7/2039; H05K 7/20327; H05K 7/20336

(57) ABSTRACT

A heat sink for cooling a heat generating device comprises: a housing, comprising: a heat transfer block for receiving heat from the heat generating device; and side walls, extending from the heat transfer block, the heat transfer block and side walls together defining an internal volume for receiving a coolant from external the heat sink; and a plurality of heat pipes and/or vapour chambers, each heat pipe and/or vapour chamber extending from the heat transfer block within the internal volume. A cooled electronic system comprises: an electronic device that generates heat in use, heat being dissipated from the electronic device through an external surface of the electronic device; and the heat sink, having the heat transfer block mounted on the external surface of the electronic device.

### TECHNICAL FIELD OF THE DISCLOSURE

The disclosure concerns a heat sink and a cooled electronic system comprising the heat sink. Methods of manufacture and/or operation of the heat sink and/or the cooled electronic system are also disclosed.

### BACKGROUND OF THE DISCLOSURE

Computers, servers, and other devices used for data processing (referred to as Information Technology or IT) typically comprise printed circuit boards (PCBs). On these PCBs are devices called Integrated Circuits (IC), which may include central processing units (CPUs), Application Specific Integrated Circuits (ASICs), Graphical Processing Units (GPUs), Random-Access Memory (RAM), etc. All of these electronic components or devices generate heat when in use. In order to maximise the performance of the IT, heat should be transferred away, in order to maintain the contents at an optimal temperature. These considerations also apply to other types of electronic devices or systems.

Typically, the electronic components or devices that are used on or in IT are cooled using air. This usually includes a heat sink of some kind with fins or similar being placed in contact with the chip surface either directly, or with a TIM (thermal interface material) between the two components. In addition to the heat sink, a series of fans may pull air across the heat sink and transferring heat away from the electronics. This type of heat sink is used in combination with additional cooling in the facility where the electronics is located (for example, a server centre), such as air conditioning. This method of cooling is not especially efficient, has a high running cost, and uses large amounts of space for managing the air used for cooling.

This method of cooling IT has been used almost exclusively for mass-manufactured IT and server equipment. However, in more recent times, the peak performance of the heat generating chips has been throttled due to the limitations of cooling a device with air. As technology halves in size for the same performance every couple of years (as exemplified in Moore's law), the heat produced by chips is increasing as the footprint of the component decreases.

In addition to air cooling (or as an alternative), a cold plate may be positioned adjacent the hot electronic components or devices, for example as described in International Patent Publication WO-03/107728 A1. A cold plate is a form of heat sink, in which coolant flows through the cold plate and thereby carries heat away. Such systems may be more efficient than cooling approaches relying on air only, but at the cost of increased complexity.

Another method for cooling IT uses immersion (direct to chip, partial or complete submersion) in a dielectric coolant. International Patent Publication WO-2019/048864 describes heat sinks and heat sink arrangements for use in immersion cooling. A heat sink may be used to collect dielectric coolant adjacent the device to be cooled and thereby provide targeted cooling. Such heat sinks may have some similarities with a cold plate, except that coolant may overflow or flow out from the heat sink and thereby cool additional devices within the same outer housing or chassis.

As the operation temperature of electronics increases, it is desirable to achieve a higher efficiency and/or heat transfer capacity of a heat sink (a cold plate, a heat sink for dielectric cooling or otherwise) for IT and other applications. This is a significant challenge.

### SUMMARY OF THE DISCLOSURE

Against this background, there is provided a heat sink in accordance with claim 1 and a cooled electronic system according to claim 20. Further preferable and/or advantageous features are identified in the dependent claims and in the remaining disclosure herein. A method of manufacturing and/or operating such a heat sink or cooled electronic system, having steps corresponding with the structural features described herein, may also be considered.

A heat sink is provided having heat pipes and/or vapour chambers within an internal volume that also receives a coolant fluid (typically, a liquid and usually not changing in phase). The coolant is normally provided from outside the heat sink and after passing through the internal volume, leaves the internal volume. The heat pipes and/or vapour chambers advantageously extend from a heat transfer surface or block at a base of the heat sink. The heat pipes and/or vapour chambers, which are normally elongated, carry heat from the base to an upper portion of the internal volume. This promotes efficient transfer of heat away from the heat transfer surface, resulting in a high thermal capacity.

In an embodiment, the heat sink has a housing, comprising the heat transfer block and side walls, extending from the heat transfer block. The heat transfer block and side walls together define the internal volume. The heat pipes typically each extend generally parallel to one another. Preferably, the heat pipes and/or vapour chambers extend substantially perpendicular to a plane of the heat transfer block and/or substantially parallel to the side walls. The heat transfer block may have a generally planar surface and/or may be generally planar in shape. This arrangement may allow a high density of heat pipes and/or vapour chambers conducting from heat transfer surface.

The heat sink is typically tall, in that the length of one, some or all of the heat pipes and/or vapour chambers (and by extension, the side walls) is longer than a dimension of the base (that is the heat transfer surface), such as a width, length or diagonal size (if the base has a rectangular or square profile) or a radius or diameter (if the base has a polygonal, round or circular profile).

In certain embodiments, the housing also has a lid, which may be distal the heat transfer block. If the lid is arranged to seal the internal volume, the heat sink may be termed a cold plate. Embodiments without a lid, with a partial lid and/or a lid that does not seal the internal volume may be used for immersion cooling. In such embodiments, the heat sink may be configured for coolant to flow out of the internal volume and be used for direct cooling of other devices.

The heat sink may further comprise: a coolant inlet for receiving coolant from external the heat sink to the internal volume; and a coolant outlet, for coolant to leave the internal volume and be transferred external the heat sink. Typically, the coolant inlet is closer to the heat transfer block and the coolant outlet is more distal the heat transfer block, but this may be reversed in embodiments. Where the coolant outlet is nearer the heat transfer block, it may include a pipe that receives coolant and carries the coolant upwards away from the heat transfer block. This may promote collection of coolant within the internal volume. A respective part (for instance, a connection port) of the coolant inlet and/or coolant outlet may be removably coupled to the housing.

In some implementations, the coolant inlet may be provided in the lid. This arrangement may mean that the coolest coolant enters the internal volume of the heat sink distal the heat transfer surface, thereby maximising a temperature difference along the heat pipes and making heat transfer more efficient. Also, the flow may be balanced so that the flow penetrates the full length of the heat pipes. Coolant may flow from the coolant inlet to the base and then from the base (via the heat pipes and/or vapour chambers) to the outlet. Optionally, the coolant outlet may be provided in the lid. The coolant inlet may be co-linear with the heat pipes and/or vapour chambers. The coolant contact with a surface area of the heat pipes can thereby be maximised without the need for surface extension fins on the heat pipes. In this case, the coolant inlet is in a centre of the lid, which may also allow more balanced or more uniformly distributed flow of coolant within the internal volume.

In a cold plate implementation, a manifold may cause coolant from the coolant inlet to flow to a plurality of locations at the base of the plurality of heat pipes and/or vapour chambers. In other words, the manifold may allow the incoming (and therefore coolest) coolant to flow directly to multiple locations at the base of the heat pipes and/or vapour chambers. This may promote efficient flow of coolant within the cold plate and efficient cooling. The locations may be symmetrically arranged across the base of the heat pipes and/or vapour chambers (and/or in a plane parallel to the heat transfer block, or at least a surface of the heat transfer block to which the heat pipes are proximal). In some embodiments, the housing may define the manifold and/or the manifold may be integral with the housing.

The structure of the housing and/or sidewalls may be modular. For example, the side walls may be formed from a modules, each of which defines a portion of the side walls. The modules may then be stacked (on the heat transfer block) to define the internal volume.

Advantageously, the heat pipes and/or vapour chambers are arranged in a regular pattern. This may especially apply when heat pipes are used In one beneficial patter, an angle between a centre of each heat pipe and one or more respective adjacent heat pipes is about 60 degrees (for example, 45 to 75 degrees, 55 to 65 degrees, 57 to 63 degrees, 58 to 62 degrees or 59 to 61 degrees).

The heat pipes and/or vapour chambers may all be the same. However, in certain embodiments, the heat pipes and/or vapour chambers are not all the same, in particular not having the same cross-sectional sizes and/or shapes (the section being taken across the elongated dimension). This may improve the compactness of heat pipes and/or vapour chambers. For example, the heat pipes and/or vapour chambers may be divided into two sets having different cross-sectional areas from each other (but optionally, otherwise the same). The two sets of heat pipes may be interspersed (or alternated) with each other. This may allow a tighter spacing of heat pipes and/or vapour chambers, such that more surface area of heat pipe and/or vapour chamber may be provided in the internal volume. More than two sets of heat pipes or vapour chambers, each set having a different sectional area might be considered. The sectional shape of the heat pipes or vapour chambers (for example in each set) may be the same or different. Possible cross-sectional shapes include circular, polygonal (in particular, rectangular or hexagonal) or fin-shaped (especially for vapour chambers). Sets of heat pipes and/or vapour chambers that differ only by shape may also be considered.

The transfer of heat to the coolant may occur in different ways. In one embodiment, the heat pipes and/or vapour chambers are soldered or metallurgically bonded into the heat transfer block. Additionally or alternatively, heat may conduct up (that is, away from the heat transfer block) along the side walls between heat pipes. Each heat pipe and/or vapour chambers may be positioned within a respective hole in the heat transfer block.

In another implementation, the heat transfer block may comprise a vapour chamber (internally). More preferably, the heat pipes and/or vapour chambers that extend from the heat transfer block may be integral with the vapour chamber of the heat transfer block (that is the vapour chamber within the heat transfer block may extend within the heat pipes and/or vapour chambers extending from it).

Baffles within the internal volume may each direct flow of coolant towards or away from one or more respective heat pipes and/or vapour chambers. A particular implementation uses generally planar baffles. These may be vertically distributed in the internal volume (that is, along a direction away from the heat transfer block). Then, adjacent baffles may cover a different portion of a cross-sectional area of the internal volume, for instance alternating between different or opposing side walls. This may thereby cause the coolant to flow across multiple heat pipes and/or vapour chambers. In embodiments, insulation around the outside of the housing may also help to cause heat transfer via the coolant and away from the heat sink and its surroundings.

The heat sink may be provided as part of a cooled electronic system (for example a computing module). An electronic device, such as a computer chip or circuit may generate heat in use, with the heat being dissipated through an external surface. The heat transfer block of the heat sink may be mounted on the external surface of the electronic device, for example such that an external surface of the heat transfer block is coplanar with the external surface of the electronic device. Heat may efficiently be transferred away from the electronic device and to the coolant within the heat sink. The system may have a chassis with the electronic device and heat sink being located within the chassis.

The external surface of the electronic device has a heat profile in use (for example, certain areas may be hotter and others cooler). Optionally, the coolant inlet of the heat sink and/or the centre of the heat transfer block is aligned with (for instance, directly adjacent to) a hottest part of the heat profile.

There may be other electronic devices to be cooled within the chassis, in addition to the electronic device being cooled by the heat sink. Coolant flowing out from the heat sink may be directed to flow over one or more of the other electronic devices, in particular in order to cool the one or more of the other electronic devices.

A heat exchanger may receive coolant from the heat sink and transfer heat from the coolant to a heat sink. A piping arrangement may transport coolant between the heat exchanger and the heat sink. A pump (for example coupled within the piping arrangement) may cause flow of the coolant between the between the heat exchanger and the heat sink. The heat exchanger may be located within or outside the chassis.

### BRIEF DESCRIPTION OF THE DRAWINGS

The disclosure may be put into practice in a number of ways and preferred embodiments will now be described by way of example only and with reference to the accompanying drawings, in which:

FIG. 1 depicts an isometric view of a heat sink mounted on an electronic device comprising at least one component to be cooled, in accordance with a first embodiment;

FIG. 2 shows a side view of the embodiment of FIG. 1;

FIG. 3 shows a plan sectional view of the embodiment of FIG. 1, along a section A-A shown in FIG. 2;

FIG. 4 shows a front view of the embodiment of FIG. 1;

FIG. 5 shows a side sectional view of the embodiment of FIG. 1, along a section B-B shown in FIG. 4;

FIG. 6 illustrates an isometric view of the heat sink alone from the embodiment of FIG. 1;

FIG. 7 depicts a plan view of the heat sink of FIG. 6;

FIG. 8 depicts a side view of the heat sink of FIG. 6;

FIG. 9 depicts a front view of the heat sink of FIG. 6;

FIG. 10 shows an exploded isometric view of the heat sink of FIG. 6;

FIG. 11 illustrates an isometric view of the electronic component alone from the embodiment of FIG. 1;

FIG. 12 depicts a plan view of the electronic component of FIG. 11;

FIG. 13 depicts a side view of the electronic component of FIG. 11;

FIG. 14 depicts an isometric view of a heat sink in accordance with a second embodiment;

FIG. 15 shows a side view of the embodiment of FIG. 14;

FIG. 16 shows an exploded isometric view of the heat sink of FIG. 14;

FIG. 17 shows an exploded isometric view of a heat sink in accordance with a third embodiment;

FIG. 18 shows a side view of the embodiment of FIG. 17;

FIG. 19 shows a plan sectional view of the embodiment of FIG. 17, along a section D-D shown in FIG. 18;

FIG. 20 shows an exploded isometric view of a heat sink in accordance with a fourth embodiment;

FIG. 21 shows a front view of the embodiment of FIG. 20; and

FIG. 22 shows a side sectional view of the embodiment of FIG. 20, along a section F-F shown in FIG. 21.

All drawings are schematic in nature. Identical components are illustrated in different drawings using the same reference numerals.

### DETAILED DESCRIPTION OF PREFERRED EMBODIMENTS

As discussed above, the present disclosure is discussed with respect to a generalised heat sink. This may include a cold plate, an open cold plate (a cold plate that allows coolant to flow out of the cold plate) and a heat sink for immersion cooling, such as described in WO-2019/048864). It may also be applied to other types of heat sink. The heat sink comprises a heat transfer block, typically coplanar with the heat source (an electronic device, for example a packaged integrated circuit or collection of components, which may be mounted on a circuit board).

Heat pipes are fixed into the heat transfer block. The heat pipes are generally oriented perpendicular to the plane of the heat transfer block and/or heat-source. This may allow an increased density of heat pipes conducting from the heat source footprint. They are typically elongated and may be tall, especially relative the dimensions of the heat transfer block heat sink surface. The use of heat pipes in this way may promote significant removal of heat from a small area. For example, 600 W of thermal power may be removed from a square planar heat transfer block of heat sink surface dimensions 55 mm×55 mm. The heat pipes are densely packed, as will be discussed below.

The heat pipes may be soldered or metallurgically bonded into the heat transfer block. This may minimise the distance between the heat source and the heat pipe, while allowing the heat to be conducted along the walls between heat pipes, perpendicular to the heat source, past the potentially less efficient, crimped end of the heat pipe.

Use of a modular housing (in segments) may also be beneficial. In particular, different heat pipe lengths may be used for different cooling requirements or the heat sink housing height can be changed with regard to space requirements (for instance in an outer chassis). In principle, the housing can be stacked to any required height.

Before discussing a specific embodiment of a heat sink according to the disclosure, the disclosure will first be discussed in more general terms. In these terms, there may be considered a heat sink for cooling a heat generating device, comprising: a housing, comprising: a heat transfer block for receiving heat from the heat generating device; and side walls, extending from the heat transfer block, the heat transfer block and side walls together defining an internal volume for receiving a coolant from external the heat sink; and a plurality of (elongated) heat pipes, each heat pipe extending (for example, parallel) from the heat transfer block within the internal volume. Thus, the heat pipes extend into the internal volume and do not only sit within the heat transfer block. This allows more heat pipes to be arranged within the heat sink than previously considered. Only a small portion (up to or less than 1%, 2%, 5%, 7.5%, 10% or 15% of the length of the heat pipe) may be in contact with the heat transfer block in some implementations.

Although the term heat pipes is used here, it is understood that the terms “heat pipe” and “vapour chamber” are often used to describe similar types of device having different shapes. A heat pipe typically has a pipe-like (or pin-like) shape, whereas a vapour chamber is generally flatter (more planar and/or fin-shaped, for instance). The additional and/or alternative use of vapour chambers will be discussed further below.

The side walls may be formed from a plurality of modules. Each module may then define a portion of the side walls. For example, the modules may then be stacked on the heat transfer block to define the internal volume. The coolant is typically a liquid (and preferably the heat sink is configured to maintain the coolant in this phase). Preferably, the plurality of heat pipes are soldered or metallurgically bonded into the heat transfer block.

In another aspect, there may be considered a cooled electronic system, comprising: an electronic device that generates heat in use, heat being dissipated from the electronic device through an external surface of the electronic device; and a heat sink as disclosed herein, having the heat transfer block mounted on the external surface of the electronic device. For example, an external surface of the heat transfer block may be coplanar with the external surface of the electronic device. The system may further comprise a chassis and the electronic device and heat sink are typically located within the chassis.

A specific embodiment will now be detailed. Further reference to this generalised sense of the disclosure will be made again subsequently below.

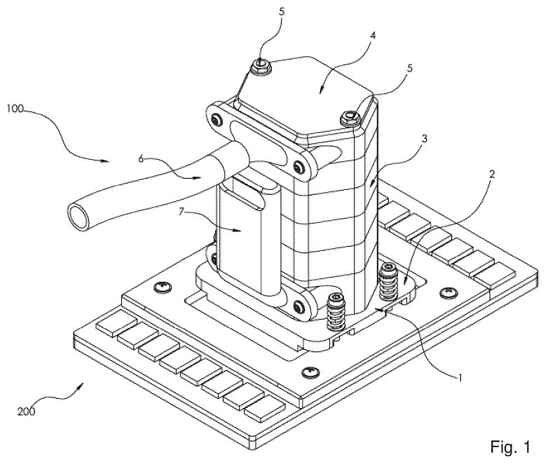

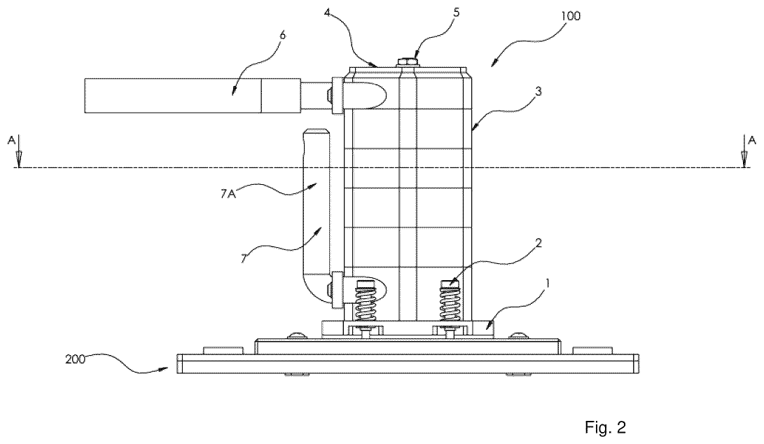

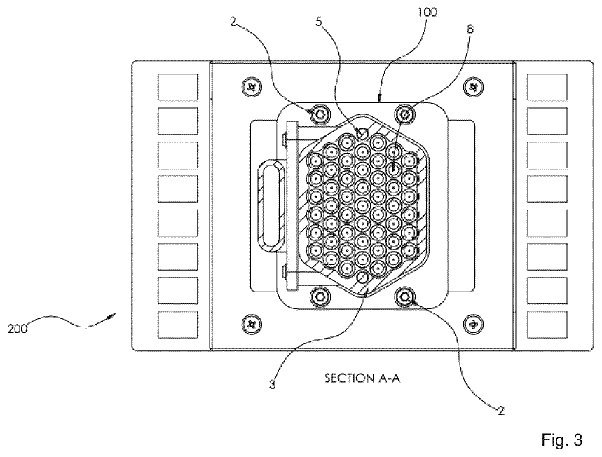

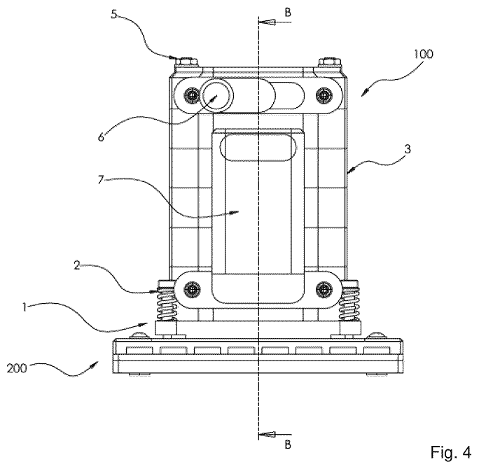

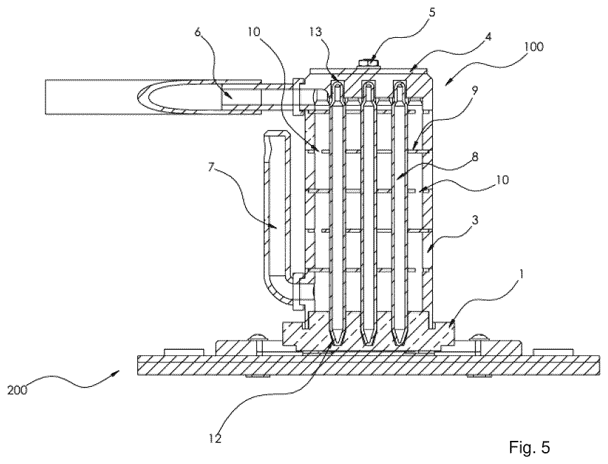

Referring now to FIGS. 1 to 5, there is depicted a heat sink 100 mounted on an electronic device 200 comprising at least one component to be cooled in accordance with a first embodiment, showing: an isometric view in FIG. 1; a side view in FIG. 2; a plan sectional view in FIG. 3; a front view in FIG. 4; and a side sectional view in FIG. 5.

The heat sink 100 comprises: a base plate 1; spring arrangements 2; a housing 3; a top plate (lid) 4; and tie bars 5. The heat sink 100 further includes: an inlet arrangement 6; and an outlet arrangement 7. Within the heat sink 100 are provided: heat pipes 8; and baffle plates 9, defining gaps 10, which will be discussed further below. Heat sink 100 is used for immersion (dielectric) cooling, rather than a cold plate with a closed coolant (water) circuit.

The housing 3 is made from stacked components. Each component (module or segment) has the same size and shape and by stacking a certain number of the housing components, a height of the housing 3 can be set. The outer shape of the housing 3 is generally cuboid, but this is not essential. The housing 3 defines an internal volume for collection of coolant, as will be discussed further below. Thus, using different numbers of segments for housing 3 may change the height of the heat sink 100 and more specifically, its internal volume, for example to accommodate different cooling requirements or space constraints. Typical heat sinks are relatively planar, with a height dimension that is normally smaller than a length and/or width. In contrast, the heat sink 100 has a relatively tall shape: the height dimension (of the housing 3) is greater than the length and/or width dimensions (and possibly the diagonal length) of the base plate 1.

In this embodiment, the segments of housing 3 are made from plastic. This may make the housing thermally (and electrically) insulative, improving the thermal performance. In particular, it may minimise heat transfer to the surrounding environment and thereby improve efficiency of the heat sink. The top plate 4 may be used to add rigidity to the plastic stacked segments of housing 3. The segments are held together with tie bars 5.

The electronic device 200 comprises at least one (and typically more than one) electronic component, such as a packaged integrated circuit. The base plate 1 is mounted to the electronic component with spring arrangements 2 (typically comprising springs and screws) to provide a force on a thermal interface material (TIM, not shown) between the base plate 1 and the electronic device 200. The base plate 1 may thus be considered a heat transfer block, as it is configured to receive heat from the electronic device 200 (by conduction). The base plate 1 has a generally planar rectangular or square shape.

As discussed above, the heat sink 100 is designed for immersion cooling (in particular, using a dielectric) and other components in the same chassis (not shown) as the heat sink 100 and electronic device 200 are cooled by the same coolant flowing through the heat sink 100. In the embodiment shown, the coolant inlet 6 is at the top of the housing 3 and the coolant outlet 7 is at the bottom of the housing 3. Since coolant enters through the coolant inlet 6 furthest from the heat-source, the temperature difference along the heat pipes 8 may be maximised. In this instance the outlet 7 includes a upward portion 7A, which is configured to raise up the dielectric coolant, such that it overflows the outlet 7 at as high a point (distal the base plate 1) as possible. This is intended to cause the heat sink housing 3 to be always full of coolant. The overflow dielectric coolant can then cool additional components, for example on a baseboard of the electronic device 200 (as will be discussed further below).

Particular reference is made to FIG. 3, in which there is shown a plan sectional view of the embodiment of FIG. 1, along a section A-A (shown in FIG. 2). This section A-A is cut directly through the housing segments 3 and the heat pipes 8. This drawing depicts 49 heat pipes with a spacing between each heat pipe of 6.8 mm and a 60 degree pitch. The staggered pattern (due to the pitch angle) may force the coolant to spread across all the heat pipes 8. The housing segments 3 are advantageously shaped on their inside to conform to the outer shape of the heat pipes 8, which may prevent coolant from bypassing the heat pipes. In the embodiment depicted, the heat pipes 8 all have the same shape and cross-sectional area, but this is not considered essential. The cross-sectional form of the heat pipes 8 is considered to provide a high surface contact area at the interface between the coolant fluid and the heat pipe 8, as the flow moves around circumferential paths.

The pattern shown for the heat pipes 8 is considered to be one of the densest patterns achievable whilst still maintaining sufficient coolant flow and ensuring enough contact area between the coolant and the heat pipes 8. This pattern may also prevent direct flow across the heat pipes 8 and/or straight line fluid flow from the inlet 6 to the outlet 7. Rather, a turbulent flow is caused that spreads across all the heat pipes 8, ensuring even contact and may also stop any coolant from bypassing any of the heat pipes 8. This configuration is suitable for cooling electronic devices 200 with a high heat output. It has been found to have superior thermal performance compared with a heat sink having densely packed horizontally-oriented heat pipes. The vertical orientation of the heat pipes 8 in this embodiment (that is, substantially perpendicular to the base plate 1) allows the use of significantly more heat pipes 8. It has been found that a high number of heat pipes is desirable for thermal performance. Orienting the heat pipes horizontally would permit approximately 6 heat pipes, compared with the 49 heat pipes 8 of the embodiment shown.

Specific reference is also made to FIG. 5, illustrating a side sectional view of the embodiment of FIG. 1, along a vertical section B-B (shown in FIG. 4) through the centre. This shows a path for the coolant to take from the inlet 6 to the outlet 7 and across the heat pipes 8. It also shows that the heat pipes are mounted into the base plate 1, by soldering into holes 12 formed in the base plate 1. The shape of each hole 12 in the base plate 1 is as closely matched as possible to the shape of the respective heat pipe 8, so that minimum solder is used. This may reduce the thermal resistance and improve the performance. Another desirable parameter to control is a depth that each heat pipe 8 is inserted into the base plate 1 (which may be governed by the height of the respective hole 12). Each heat pipe 8 has a thicker metal at one end (tip). Specifically, one end of the heat pipe 8 is pointed (crimped or tapered), whilst the other end is rounded. The pointed end of the heat pipe 8 is inserted into the hole 12. By configuring the depth of each hole 12, sufficient contact between the heat pipe 8 and the base plate 1 may be set to optimise heat transfer from the base plate 1 into the vapour inside the heat pipe 8. The rounded end of each heat pipe 8 is inserted into a respective hole 13 formed in the top plate 4.

Baffle plates 9 are stacked horizontally along the vertical heat pipes 8. They are advantageously trapped between each segment of the housing 3 for easy assembly. The baffle plates 9 create horizontally oriented chambers (that is elongated perpendicular to the elongation direction of the housing 3) that cause the coolant to flow horizontally across the heat pipes 8. Each baffle plate 10 has a gap 10 along its side to allow coolant to pass vertically to the next chamber. The gaps alternate sides (that is from left to right) to force the coolant to follow a ‘zigzag’ flow pattern along the elongated length of the heat pipes 8. This may cause the coolant to pass over the same heat pipe 8 multiple times and thereby may optimise heat transfer by utilising the full length of the heat pipe 8 (that is, forcing the dielectric coolant to contact as much of the heat pipe 8 as possible along its full length). Alternating the side of gap 10 may be achieved simply by stacking identical baffle plates 9 in alternate positions.

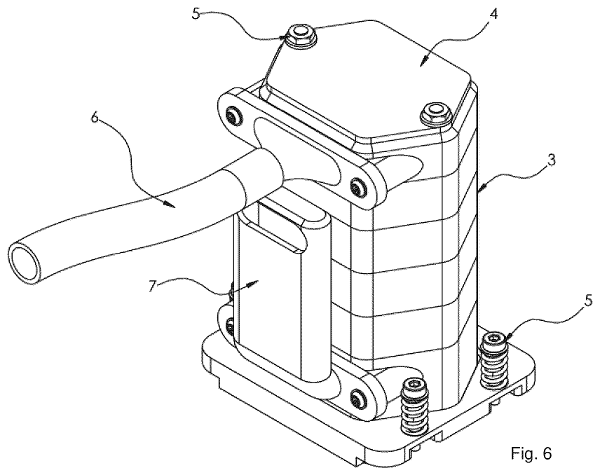

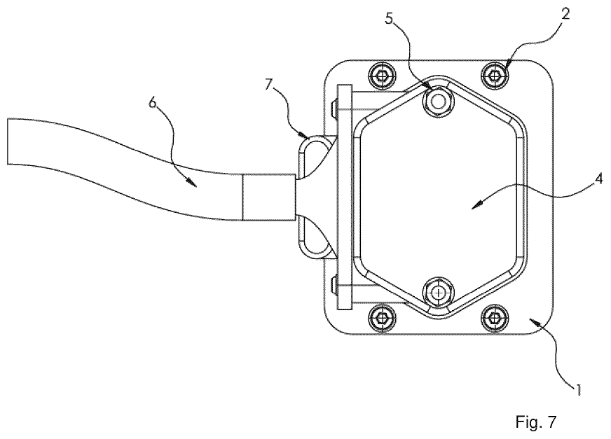

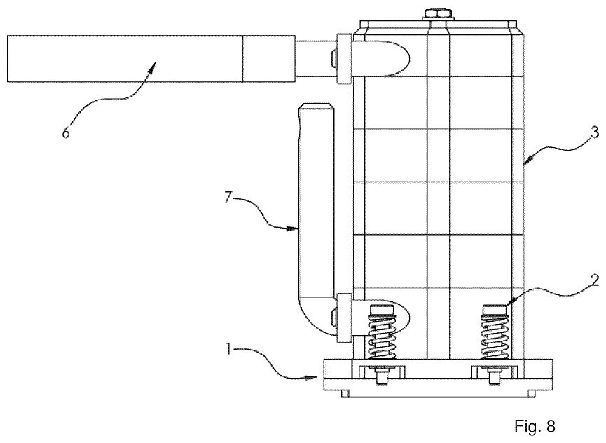

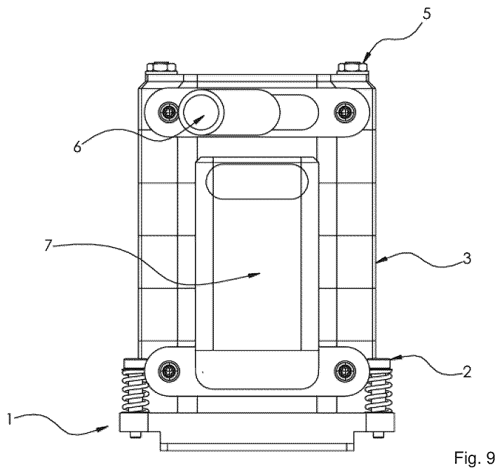

Referring now made to FIGS. 6 to 9, there is depicted the heat sink 100 alone of the embodiment discussed above, showing: an isometric view in FIG. 6; a plan view in FIG. 7; a side view in FIG. 8; and a front view in FIG. 9. All of the features shown in these drawings have been discussed above and will therefore not be detailed again here.

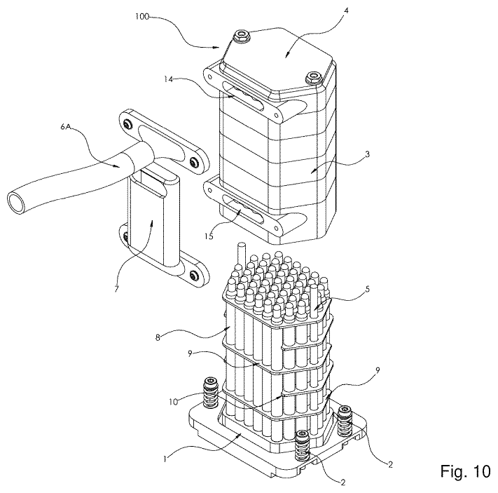

Next referring to FIG. 10, there is shown an exploded isometric view of the heat sink of FIG. 6. Here, the baffle plates 9 and gaps 10 are shown from a different perspective. In addition, the structure of the coolant inlet 6 is shown, comprising a housing aperture 14 and a piping arrangement 6A, removably coupled to the aperture 14. Likewise, the structure of the coolant outlet 7 is shown, comprising a housing aperture 15 and the upward portion 7A, removably coupled to the aperture 15.

It will be understood that the heat sink 100 and electronic device 200 are arranged within a chassis (not shown). In an immersion cooled approach, according to the embodiment shown, this chassis is configured to collect the effluent coolant from the heat sink (which may flow over other components on the electronic device 200 or elsewhere in the chassis before or after collecting). A pump, typically within the chassis, causes the coolant to flow within the chassis, although convective flow of the coolant may additionally or alternatively cause movement of the coolant. A heat exchanger may be provided, preferably within the chassis, to transfer heat from the dielectric coolant to a secondary coolant (for example water or water-based coolant). The heat exchanger may also be configured to maintain the dielectric (primary) coolant in a single (liquid) phase. More details about such arrangements are provided at least in WO-2019/048864, incorporated by reference in its entirety.

Referring again to the generalised sense of the disclosure discussed above, further optional and/or advantageous features may be considered. For example, the heat transfer block may have a generally planar surface and/or be generally planar. In some embodiments, the housing further comprises a lid. Optionally, the housing is made of a thermally insulative material.

In embodiments, the plurality of heat pipes may extend substantially perpendicular to a plane of the heat transfer block. Additionally or alternatively, the heat pipes may extend substantially parallel to the side walls (of the housing).

Preferably, a length of at least one (more preferably some and optionally all) of the plurality of heat pipes is greater than a dimension of the heat transfer block (for example, one or more of the width, length, diagonal size, radius, diameter of the heat transfer block).

The heat sink may further comprise: a coolant inlet for receiving coolant from external the heat sink to the internal volume; and a coolant outlet, for coolant to leave the internal volume and be transferred external the heat sink. If the coolant inlet is at a part of the housing proximal the heat transfer block, the coolant outlet is typically at a part of the housing distal the heat transfer block and conversely, if the coolant outlet is at a part of the housing proximal the heat transfer block, the coolant inlet may be at a part of the housing distal the heat transfer block. In the latter case, the coolant outlet may comprise a pipe configured to receive coolant from a part of the internal volume relatively close (proximal) to the heat transfer block and carry or direct the received coolant (relatively) distal the heat transfer block (in a direction perpendicular to a plane of the heat transfer block, which may be upwardly or vertically, for instance). The coolant may then exit the heat sink at such a distal location. Advantageously, the coolant inlet and/or coolant outlet each comprise a connection port that is removably coupled to the housing (for example, by a push-fit or screw connection).

The plurality of heat pipes may be arranged in a regular pattern. For example, an angle between a centre of each heat pipe and one or more respective adjacent heat pipes may be 60 degrees.

In embodiments, each of the plurality of heat pipes is positioned within a respective hole in the heat transfer block. The side walls may be arranged such that heat is conducted along the side walls between heat pipes, perpendicular to the heat transfer block.

Beneficially, the heat sink further comprises one or more baffles arranged within the internal volume to direct flow of coolant towards, away from or across at least one heat pipe of the plurality of heat pipes. Preferably, the one or more baffles comprise a plurality of generally planar baffles distributed in the internal volume along a direction away from the heat transfer block. In this case, adjacent baffles may cover a different portion of a cross-sectional area of the internal volume. For example, adjacent baffles may alternate between different or opposing side walls. In any event, the baffles may be arranged to cause the coolant to flow across multiple heat pipes.

In respect of the cooled electronic system discussed above, further details may be considered. For example, the system may further comprise a heat exchanger, configured to receive coolant from the heat sink and to transfer heat from the coolant to a heat dissipation fluid (for example, a secondary coolant). Optionally, a piping arrangement may be arranged to transport coolant between the heat exchanger and the heat sink. The heat exchanger may be located within or outside the chassis. Additionally or alternatively, a pump may be provided to cause the coolant to flow. The pump may be arranged to cause flow of the coolant between the between the heat exchanger and the heat sink. The pump may be located within or outside the chassis.

Preferably, the electronic device is a first electronic device and the cooled electronic system further comprises a second electronic device. The second electronic device may be arranged such that coolant flowing out from the heat sink flows over or across the second electronic device (for cooling the second electronic device).

Further reference will be made to the generalised sense of the disclosure again below. First, further details of the specific embodiment and other arrangements will be considered.

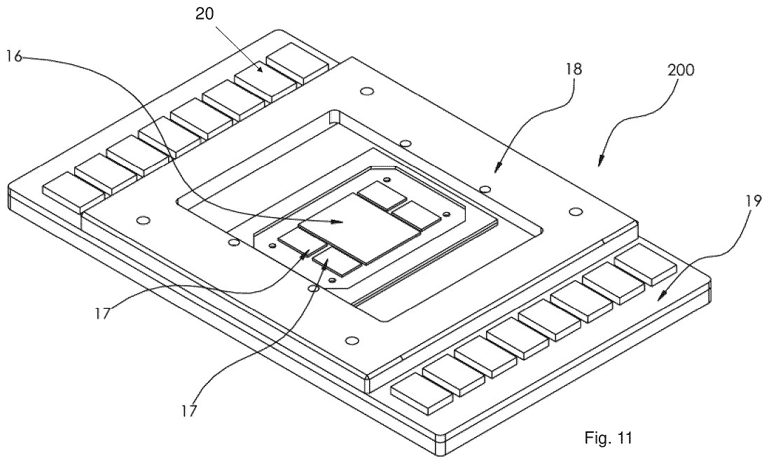

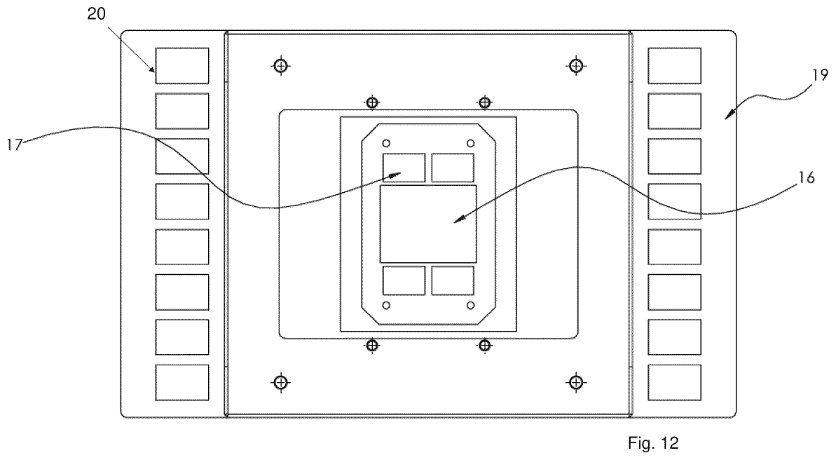

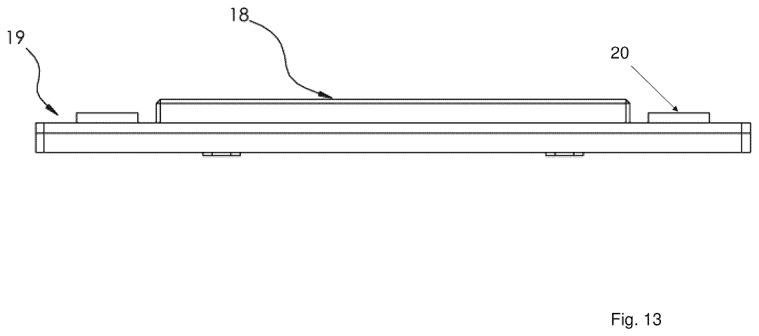

Reference is now made to FIGS. 10 to 13, in which there is depicted the electronic device 200 alone of the embodiment discussed above, showing: an isometric view in FIG. 11; a plan view in FIG. 12; and a side view in FIG. 13. Some of the features shown in these drawings have been discussed above, but these will now be considered in more depth. The electronic device 200 comprises: a baseboard (or circuit board) 19; a main processor chip 16; chiplets 17; and auxiliary components 20. This is purely an example of an electronic device that might be cooled by the heat sink 100 and is not considered limiting.

The main processor 16 is in the centre of the baseboard or PCB 19 with four chiplets 17 mounted to surround the main processor 16 in close proximity. Such close proximity is becoming more common because it may improve communication speed between the chiplet 17 and the main processor 16. In this instance, the main processor 16 and chiplets 17 are all co-planar and may be cooled by the heat sink 100 with a base plate 1 that has a planar lower surface. In other instances, the chips 16, 17 may be at different heights. Then, the base plate 1 of the heat sink 100 may be shaped to conform to the profile of the chips 16, 17.

A socket 18 is provided on the electronic device 200, upon which the heat sink 100 can be mounted. An actual socket 18 may have a slightly different appearance than shown in the drawings. The spring arrangements 2 on the heat sink 100 may mount directly into the socket 18. As discussed above, auxiliary electrical components 20 on the baseboard 19 may be cooled with the dielectric overflow from the coolant outlet 7 of the heat sink 100.

Multiple heat sinks 100 can be provided within a single chassis in some embodiments, for instance in a grid. As an example, 6 to 12 heat sinks 100 may be provided in the same chassis.

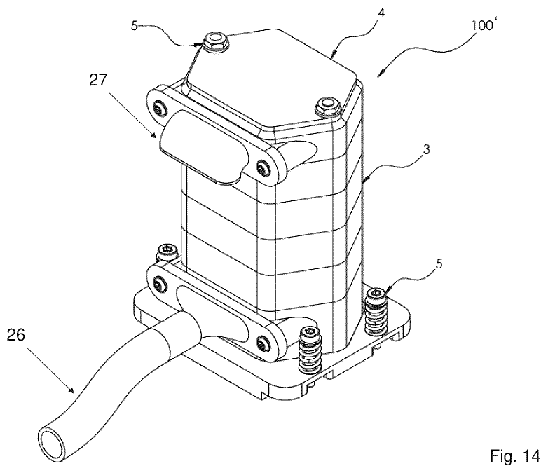

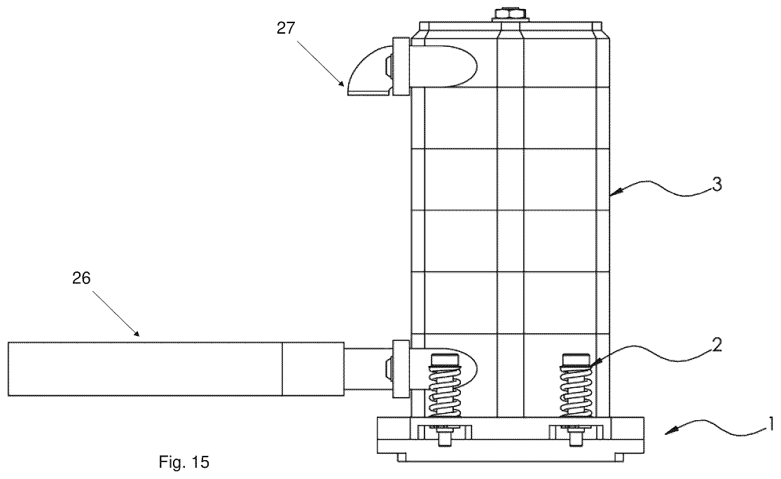

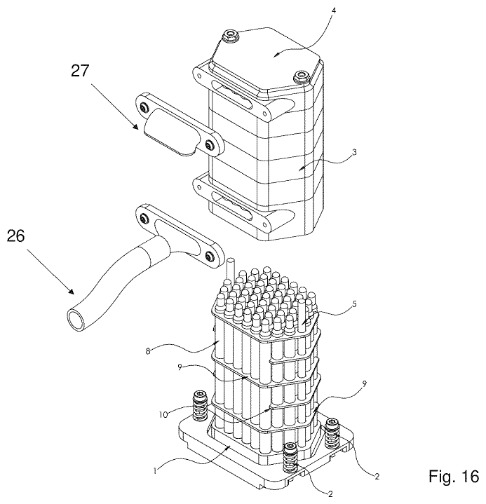

Alternative designs of heat sink are also possible. For example, a dielectric coolant inlet may be provided at the base of the heat sink and a coolant outlet may overflow from the top of the heat sink. Referring to FIG. 14, there is depicted an isometric view of a heat sink in accordance with a second embodiment, in line with this approach. Many of the details are the same as the first embodiment described above, so these will not be repeated for the sake of simplicity. Heat sink 100′ has a dielectric coolant inlet 26 towards the base or bottom and a coolant outlet 27 towards the top (that is, distal the base). It has been found that the cooling performance of the heat sink is better (although perhaps only fractionally) than that of the first embodiment. Reference is also made to FIG. 15, in which there is shown a side view of the embodiment of FIG. 14 and to FIG. 16, in which an exploded isometric view of the heat sink of FIG. 14 is shown. It will be seen from these drawings that other details of the heat sink 100′ are essentially the same as those of the heat sink 100 of the first embodiment.

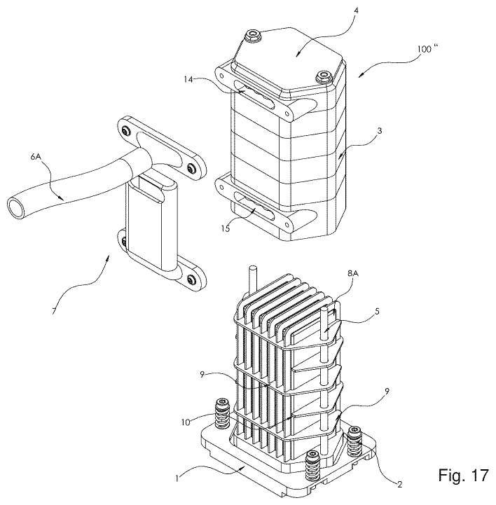

Referring next to FIG. 17, there is shown an exploded isometric view of a heat sink 100″ in accordance with a third embodiment. It will be seen from these drawings that many details of the heat sink 100″ are the same as those of the heat sink 100 of the first embodiment, so these will not be repeated for the sake of simplicity. However, this embodiment uses vapour chambers 8A instead of heat pipes. The vapour chambers 8A operate in a similar way to the heat pipes, but their outer form are fin-shaped rather than pin-shaped. Using a fin-shaped vapour chamber 8A (that is, a flat heat pipe) may spread the heat away from the centre of the heat sink. This may optimise heat transfer across the base better that the use of heat pipes alone as considered above.

As noted above, the design of this embodiment is shown similarly to the first embodiment with a dielectric coolant inlet at the top of the heat sink and a coolant outlet at a lower height, but with an upward portion, configured to raise up the dielectric coolant before overflowing. However, it will be recognised that the configuration of this design can readily be adjusted to match the second embodiment in respect of the dielectric coolant inlet and coolant outlet.

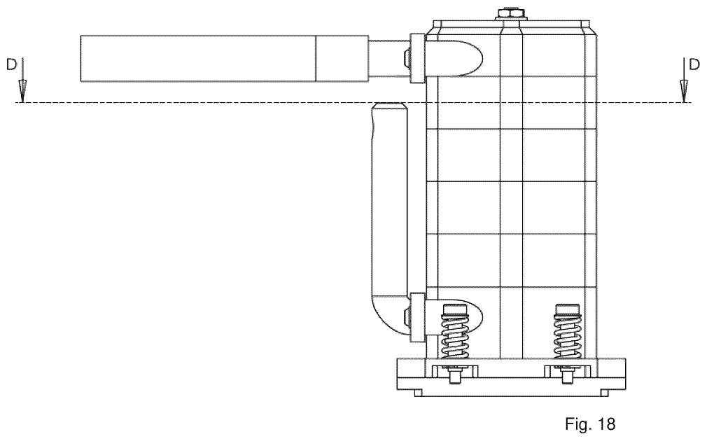

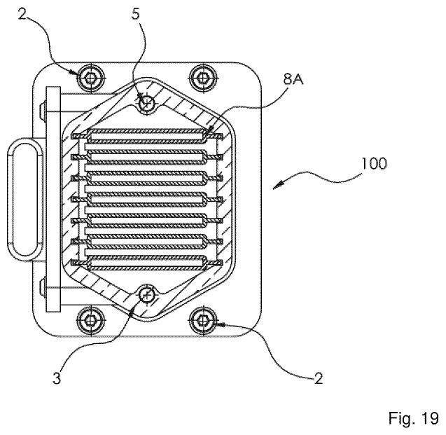

Reference is also made to FIG. 18, in which there is shown a side view of the embodiment of FIG. 17 and to FIG. 19, in which a plan sectional view of the embodiment of FIG. 17, along a section D-D shown in FIG. 18 is shown. The different internal structure of this heat sink design can be seen. However, the operation is essentially the same as described above with reference to the first embodiment.

In another design, the base plate may comprise a vapour chamber. Moreover, the heat pipes (that is, pin-shaped vapour chambers) may be made from the same vapour chamber as the base. The role of a heat sink may be considered as to diffuse the thermal energy from a small concentrated heat source out to a much larger area, over which the heat can flow by convection out to the surrounding fluid. As discussed with reference to previously-described designs above, the heat is initially transported a short distance from the heat source by conduction within the solid metal base, before then being efficiently transported by a number of heat pipes. This may provide a large wetted area for convection to the surrounding fluid. It is envisaged that, by minimising an internal thermal resistance of the heat sink, the thermal performance of the heat sink may be improved. The adaptation of the base plate may achieve this additional aim, as will be discussed below.

Thermal performance for high power density devices may be increased compared with previously-described embodiments by better spreading the heat out laterally (that is, in the plane of the heat source or base plate). This may also allow an increased number of heat pipes (and/or vapour chambers) to be engaged in the heat transfer process than in previously-described designs. Use of a solid metal base to achieve this lateral heat spread may impart a significant thermal resistance, detrimental to overall performance.

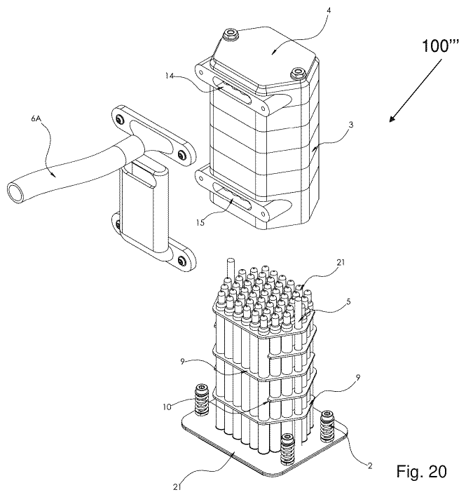

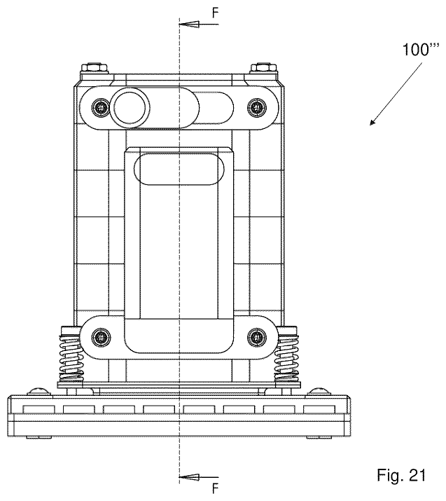

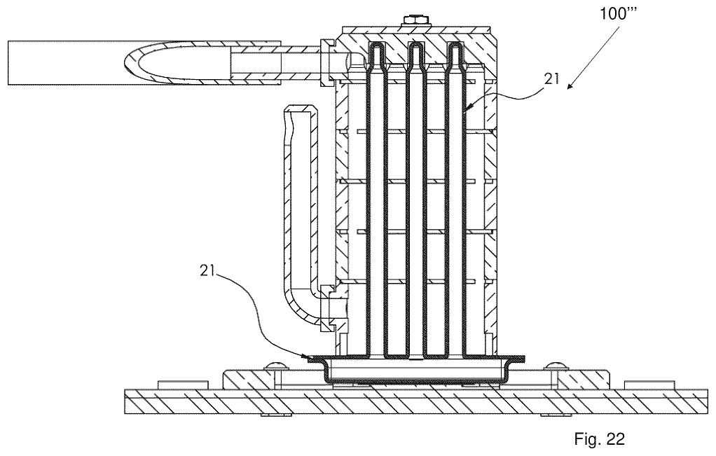

Referring now to FIG. 20, there is shows an exploded isometric view of a heat sink 100″ in accordance with such a fourth embodiment. Reference is also made to FIG. 21, showing a front view of this embodiment and FIG. 22, showing a side sectional view of the embodiment, along a section F-F shown in FIG. 21. As shown, an integrated base plate and heat pipe structure 21 is provided, comprising at least one vapour chamber (preferably forming a single vapour chamber structure). The integrated structure 21 thus uses the same two-phase heat transfer process as previously explained for within the heat pipes, to help spread the heat laterally (in the plane of the heat source). The integration of the base plate and heat pipes into a single structure 21 provides a continuous and closed internal cavity, performing both vapour chamber and heat pipe functionality. The thermal performance of this design is thus improved in comparison with the heat flow through a solid metal interface between a base plate and heat pipes or even between a vapour chamber and heat pipes.

It can also be seen that the external profile of the heat sink 100″′ would appear of approximately the same shape and dimension as the “heat-pipe heatsink” design. The surface area exposed to the surrounding fluid would be the same, as would the pressure drop imparted on that surrounding fluid.”

As with the third embodiment, the design of the fourth embodiment is shown similarly to the first embodiment with a dielectric coolant inlet at the top of the heat sink and a coolant outlet at a lower height, but with an upward portion, configured to raise up the dielectric coolant before overflowing. However, it will be recognised that the configuration of this design can readily be adjusted to match the second embodiment in respect of the dielectric coolant inlet and coolant outlet.

Returning to the general sense of the disclosure, it will be understood that heat pipes and/or vapour chambers can be used, rather than heat pipes alone. In other words, where the term heat pipe has been used above, this may be substituted by a vapour chamber.

Although specific embodiments have now been described, the skilled person will appreciate that various modifications and alternations are possible. As discussed previously, although the embodiment shown is a heat sink for immersion cooling with effluent coolant being used to cool other components within the same chassis, an alternative closed loop cold plate arrangement could be used. Although a dielectric coolant is preferred for immersion cooling, a closed loop cold plate arrangement may use different coolants, in particular water or a water-based coolant. The coolant used is preferably single phase (in other words, the heat sink is designed for the coolant to remain in liquid phase), but a two-phase coolant could be used alternatively (so that the heat sink is designed for the coolant to boil). For a cold plate, the flow of coolant is beneficially balanced so that the flow penetrates the full length of the heat pipes. A heat exchanger and/or pump for a cold plate may be provided within an outer chassis (in which the heat sink and electronic device are located) or external the chassis. The heat exchanger may transfer heat from the coolant flowing through the cold plate to another coolant fluid (which may be a liquid or gas).

In a closed cold plate (or other embodiment), the position of the coolant inlet and coolant outlet may vary. For example, in one implementation, the coolant inlet may pass through the lid approximately opposing the hottest part of the device being cooled (for instance, the centre of the top surface of the lid). The coolant outlet may pass through the lid at a side of the top surface of the lid. The coolant inlet may be co-linear with the heat pipes in certain implementations, which may allow maximum contact between the coolant fluid and the heat pipe surface area along the height dimension, without the need for heat pipe surface extension fins.

In general, it is not necessary for the coolant inlet to be located at the top of the housing and the coolant outlet to be located at the bottom of the housing. Indeed, the coolant inlet and coolant outlet of the embodiment shown in the drawings (and discussed above) can be reversed. In this case, the upward portion 7A may be omitted or replaced with a pipe. The use of removable couplings in the coolant inlet and coolant outlet allows these connections to be straightforwardly changed. Also, for a heat sink that is not a cold plate, the coolant outlet need not have an associated pipe. For example, the coolant outlet may simply comprise a hole or aperture in the housing or the top plate (lid). The coolant may simply overflow the housing. In some cases, no top plate may be provided and the coolant outlet may comprise the aperture formed by the top of the housing. Multiple coolant outlets may be provided, which for example, could be arranged symmetrically to promote equal flow distributions within the internal volume or according to a heat profile of electronic components below to cause a higher flow rate over certain parts of the heat transfer surface than others. Multiple coolant inlets may be used, but this becomes more complex.

Different configurations and/or arrangements of heat pipes are possible. For example, the shape and/or size of the heat pipes may be different from those shown. Also, heat pipes of different shape and/or size may be provided within the same heat sink. For example, an array of heat pipes with two different diameters may minimise turbulent flow and give greater heat pipe surface area than a single array. The cross-sectional shape of the heat pipe (perpendicular to the direction of elongation) may be circular, rectangular, hexagonal or otherwise. Two or more different types of heat pipe (each type having a specific shape and size) could be used in some embodiments. The heat pipe pitch spacing and/or angle can be changed, especially to optimise the thermal performance, in particular depending on the sizes and shapes of the heat pipes used.

In another option, the housing (vessel) in which the heat pipes and coolant fluid are contained may form its own manifold, directing the flow from the inlet to one or more outlet ports. The manifold may optionally cause flow from the outlet ports to be combined into a single outlet.

The heat pipes are preferably soldered into the heat transfer block, but they may be otherwise metallurgically bonded. This may minimise the distance between the heat source and the heat pipe, while allowing the heat to be conducted along the walls between heat pipes, perpendicular to the heat source and may bypass the less efficient, crimped end of the heat pipe.

The housing is preferably formed from plastic, but other materials may be used, particularly those that are thermally insulative. Additionally or alternatively, thermal insulation around the housing can be used for minimising heat transfer to the surrounding environment.

The use of baffles within the internal volume of the heat sink is advantageous and other baffle patterns can be provided (for instance to direct flow towards specific heat pipes if they are working comparatively harder, due to the heat profile of the electronic device being cooled). Optionally, no baffles might be used.

As detailed above, other versions would include a dielectric coolant inlet at the base and coolant outlet overflowing from the top. This could also be converted into a cold plate with a closed water based coolant loop if hoses were fixed to the inlet and outlet.

Embodiments using heat pipes alone and vapour chambers alone have been shown. It will be appreciated, however, that heat pipes and vapour chambers can optionally be used in combination. For example, at least one heat pipe and at least one vapour chamber may be provided extending from the heat transfer block within the internal volume of the heat sink.

In embodiments, the heat transfer block comprises a vapour chamber. Preferably, the vapour chamber of the heat transfer block is integral with the plurality of heat pipes and/or vapour chambers that extend from the heat transfer block. For example, an internal volume of the vapour chamber of the heat transfer block may be continuous with internal volumes of the plurality of heat pipes and/or vapour chambers that extend from the heat transfer block.

Returning to the general sense of the disclosure discussed above, further optional features may be considered. For example, the lid may be arranged to seal the internal volume, such that the heat sink is a cold plate.

In some implementations, the coolant inlet is co-linear with the plurality of heat pipes. Optionally, the coolant inlet is in a centre of the lid.

The housing may be configured to transport coolant from the coolant inlet to a base of the plurality of heat pipes proximal the heat transfer block. Then, the plurality of heat pipes may be arranged such that coolant flows from the base of the plurality of heat pipes to the coolant outlet. The heat sink may further comprise a manifold, arranged to cause coolant from the coolant inlet to flow to a plurality of locations at the base of the plurality of heat pipes. For example, the plurality of locations may be arranged symmetrically across the base of the plurality of heat pipes (for instance, in the plane parallel the heat transfer block). The housing may be further configured to define the manifold.

In embodiments, the plurality of heat pipes have different cross-sectional (in the elongated dimension) sizes and/or shapes. For instance, the plurality of heat pipes may comprise: a first set of heat pipes, each having a first cross-sectional area; and a second set of heat pipes, each having a second cross-sectional area that is smaller than the first cross-sectional area and each positioned in between heat pipes from the first set of heat pipes. In certain implementations, the plurality of heat pipes have a cross-sectional shape that is one of: circular; polygonal; rectangular; and hexagonal.

Optionally, the heat sink further comprises insulation arranged around an outside of the housing.

In certain embodiments, the external surface of the electronic device has a heat profile in use. Then, the coolant inlet of the heat sink may be aligned with a hottest part of the heat profile. Additionally or alternatively, a centre of the heat transfer block may aligned with (or adjacent) the hottest part of the heat profile.

All of the features disclosed herein may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

1. A heat sink for cooling a heat generating device, comprising:
a housing, comprising: a heat transfer block for receiving heat from the heat generating device; and side walls, extending from the heat transfer block, the heat transfer block and side walls together defining an internal volume for receiving a coolant from external the heat sink; and
a plurality of heat pipes and/or vapour chambers, each heat pipe and/or vapour chamber extending from the heat transfer block within the internal volume.

2. The heat sink of claim 1, wherein the plurality of heat pipes and/or vapour chambers extend substantially perpendicular to a plane of the heat transfer block and/or substantially parallel to the side walls or wherein a length of at least one of the plurality of heat pipes and/or vapour chambers is greater than a dimension of the heat transfer block.

3. (canceled)

4. The heat sink of claim 1, wherein the housing further comprises: a lid arranged to seal the internal volume, such that the heat sink is a cold plate.

5. The heat sink of claim 1, further comprising: a coolant inlet for receiving coolant from external the heat sink to the internal volume; and a coolant outlet, for coolant to leave the internal volume and be transferred external the heat sink.

6. The heat sink of claim 5, wherein the coolant outlet comprises a pipe configured to receive coolant from a part of the internal volume relatively close to the heat transfer block and carry the received coolant relatively distal the heat transfer block in a direction perpendicular to a plane of the heat transfer block or wherein the coolant inlet and/or coolant outlet each comprise a connection port that is removably coupled to the housing.

7. (canceled)

8. The heat sink of claim 1, wherein the side walls are formed from a plurality of modules, each module defining a portion of the side walls, such that that the modules are stacked on the heat transfer block to define the internal volume or wherein the plurality of heat pipes are arranged in a regular pattern, with an angle between a centre of each heat pipe and one or more respective adjacent heat pipes is 60 degrees.

9. (canceled)

10. The heat sink of claim 1, wherein the plurality of heat pipes and/or vapour chambers have different cross-sectional sizes and/or shapes.

11. The heat sink of claim 10, wherein the plurality of heat pipes and/or vapour chambers comprise:
a first set of heat pipes or vapour chambers, each having a first cross-sectional area; and
a second set of heat pipes or vapour chambers, each having a second cross-sectional area that is smaller than the first cross-sectional area and each positioned in between heat pipes or vapour chambers from the first set of heat pipes or vapour chambers.

12. The heat sink of claim 10, wherein the plurality of heat pipes and/or vapour chambers have a cross-sectional shape that is one of: circular; polygonal; rectangular; fin-shaped; and hexagonal.

13. The heat sink of claim 1, wherein the plurality of heat pipes and/or vapour chambers are soldered or metallurgically bonded into the heat transfer block, or wherein each of the plurality of heat pipes and/or vapour chambers is positioned within a respective hole in the heat transfer block.

14. (canceled)

15. The heat sink of claim 1, wherein the heat transfer block comprises a vapour chamber that is integral with the plurality of heat pipes and/or vapour chambers.

16. The heat sink of claim 1, further comprising:
one or more baffles arranged within the internal volume to direct flow of coolant towards, away from or across at least one heat pipe of the plurality of heat pipes and/or vapour chambers.

17. The heat sink of claim 16, wherein the one or more baffles comprise a plurality of generally planar baffles distributed in the internal volume along a direction away from the heat transfer block, adjacent baffles covering a different portion of a cross-sectional area of the internal volume, thereby causing the coolant to flow across multiple heat pipes and/or vapour chambers.

18. The heat sink of claim 1, wherein one or both of:
the housing is made of a thermally insulative material; and
the heat sink further comprises insulation arranged around an outside of the housing.

19. The heat sink of claim 1, wherein the coolant is a liquid.

20. A cooled electronic system, comprising:
an electronic device that generates heat in use, heat being dissipated from the electronic device through an external surface of the electronic device; and
a heat sink, comprising:
a housing, comprising: a heat transfer block for receiving heat from the heat generating device; and side walls, extending from the heat transfer block, the heat transfer block and side walls together defining an internal volume for receiving a coolant from external the heat sink; and
a plurality of heat pipes and/or vapour chambers, each heat pipe and/or vapour chamber extending from the heat transfer block within the internal volume; and
wherein the heat transfer block of the heat sink is mounted on the external surface of the electronic device.

21. The cooled electronic system of claim 20, further comprising:
a heat exchanger, configured to receive coolant from the heat sink and to transfer heat from the coolant to a heat dissipation fluid; and
a piping arrangement, arranged to transport coolant between the heat exchanger and the heat sink.

22. The cooled electronic system of claim 21, further comprising:
a pump, arranged to cause flow of the coolant between the between the heat exchanger and the heat sink.

23. The cooled electronic system of claim 20, wherein the electronic device is a first electronic device, the cooled electronic system further comprising a second electronic device, arranged such that coolant flowing out from the heat sink flows over the second electronic device.

24. The cooled electronic system of claim 20, further comprising a chassis, the electronic device and heat sink being located within the chassis.
